(19) United States
(12) Patent Application Publication
(10) Pub. No.: US 2011/0095320 A1
(43) Pub. Date: Apr. 28, 2011

(54) LIGHT EMITTING DEVICE AND LIGHT EMITTING DEVICE PACKAGE

(76) Inventor: Sung Min HWANG, Seoul (KR)

(21) Appl. No.: 12/909,236

(22) Filed: Oct. 21, 2010

(30) Foreign Application Priority Data
Oct. 22, 2009 (KR) 10-2009-0100653

(51) Int. Cl. H01L 33/60

(52) U.S. Cl. 257/98; 257/E33.067

(57) ABSTRACT

Disclosed are a light emitting device, a light emitting device package, and a lighting system. The light emitting device includes a light emitting structure including a second conductive semiconductor layer, an active layer over the second conductive semiconductor layer, and a first conductive semiconductor layer over the active layer dielectric layer in a cavity defined by removing a portion of the light emitting structure, and a second electrode layer over the dielectric layer.

### CROSS-REFERENCE TO RELATED APPLICATION

This application claims under 35 U.S.C. §119 to Korean Patent Application No. 10-2009-0100653 filed Oct. 22, 2009, which is hereby incorporated by reference in its entirety.

### BACKGROUND

The embodiment relates to a light emitting device, a light emitting device package, and a lighting system.

A light emitting device (LED) includes a p-n junction diode having a characteristic of converting electric energy into optical energy. The p-n junction diode can be formed by combining group III-V elements of the periodic table. The LED can represent various colors by adjusting the compositional ratio of compound semiconductors.

When a forward voltage is applied to the LED, electrons of an n layer are combined with holes of a p layer, so that energy corresponding to an energy gap between a conduction band and a valance band may be generated. This energy is mainly realized as heat or light, and the LED emits the energy as the light.

A nitride semiconductor represents superior thermal stability and wide band gap energy so that the nitride semiconductor has been spotlighted in the field of optical devices and high-power electronic devices. In particular, blue, green, and UV light emitting devices employing the nitride semiconductor have already been developed and extensively used.

According to the related art, a current may flow reversely when electrostatic discharge (ESD) occurs, thereby causing damage to an active layer formed in a light emitting area.

In order to prevent the LED from being damaged due to the ESD, according to the related art, Zener diode is mounted in a package in the reverse direction of the LED while connecting the Zener diode with the LED in parallel. Thus, when a constant voltage is applied, a current flows to the LED so that the LED emits the light. In addition, when the ESD occurs, the current flows to the Zener diode, so that the LED can be prevented from being damaged.

However, according to the related art, the Zener diode is mounted in the package, so that light absorption may be lowered.

In a vertical type light emitting device according to the related art, n and p type electrodes are formed at the top and bottom of the light emitting device, respectively, for current injection.

In this case, electrons and holes injected by the n and p type electrodes carry to an active layer and are combined with each other to emit light. The light may be emitted to the outside, or reflected by the n type electrode and disappeared inside the light emitting device. In other words, according to the related art, light emitted under the n type electrode is reflected by the n type electrode, so that light emission efficiency may be reduced.

In addition, according to the related art, the light reflected by the n type electrode is re-absorbed, so that heat may be emitted.

According to the related art, the life span and the reliability of the light emitting device may be lowered due to current crowding.

### BRIEF SUMMARY

The embodiment provides a light emitting device, a light emitting device package, and a lighting system, capable of preventing the light emitting device from being damaged due to ESD while preventing light absorption from being lowered.

The embodiment provides a light emitting device, a light emitting device package, and a lighting system, capable of improving light extraction efficiency while enhancing current spreading efficiency.

According to the embodiment, the light emitting device includes a light emitting structure including a second conductive semiconductor layer, an active layer over the second conductive semiconductor layer, and a first conductive semiconductor layer over the active layer, a dielectric layer in a cavity defined by removing a portion of the light emitting structure, and a second electrode layer over the dielectric layer. The second electrode includes a reflective layer over the dielectric layer, and a conductive layer over the reflective layer.

According to the embodiment, the light emitting device includes a light emitting structure including a second conductive semiconductor layer, an active layer over the second conductive semiconductor, and a first conductive semiconductor layer over the active layer, a capacitor in a cavity defined by removing a portion of the light emitting structure, and a first electrode over the light emitting structure. The capacitor includes a dielectric layer over the cavity, and a second electrode layer over the dielectric layer.

According to the embodiment, a light emitting device package includes a package body, third and fourth electrode layers installed in the package body, and a light emitting device electrically connected to the third and fourth electrode layers.

According to the embodiment, a lighting system includes a substrate and a light emitting module including a light emitting device package over the substrate. The light emitting device package includes a package body, third and fourth electrode layers installed in the package body, and the light emitting device electrically connected to the third and fourth electrode layers.

### BRIEF DESCRIPTION OF THE DRAWINGS

FIG. 1 is a sectional view showing a light emitting device according to a first embodiment;

FIG. 2 is a circuit diagram showing a light emitting device according to the embodiment;

FIG. 3 is a view showing the waveform of the light emitting device according to the embodiment when ESD occurs;

FIGS. 4 to 7 are sectional views showing the manufacturing process of the light emitting device according to the first embodiment;

FIG. 8 is a sectional view showing a light emitting device according to a second embodiment;

FIG. 9 is a sectional view showing a light emitting device according to a third embodiment;

FIG. 10 is a sectional view showing a light emitting device package according to the embodiment;

FIG. 11 is a perspective view showing a lighting unit according to the embodiment; and

FIG. 12 is an exploded perspective view showing a backlight unit according to the embodiment.

### DETAILED DESCRIPTION OF THE EMBODIMENTS

Hereinafter, a light emitting device, a light emitting device package, and a lighting system according to the embodiment will be described with respect to accompanying drawings.

In the description of embodiments, it will be understood that when a layer (or film) is referred to as being ‘on’ another layer or substrate, it can be directly on another layer or substrate, or intervening layers may also be present. Further, it will be understood that when a layer is referred to as being ‘under’ another layer, it can be directly under another layer, and one or more intervening layers may also be present. In addition, it will also be understood that when a layer is referred to as being ‘between’ two layers, it can be the only layer between the two layers, or one or more intervening layers may also be present.

### EMBODIMENT

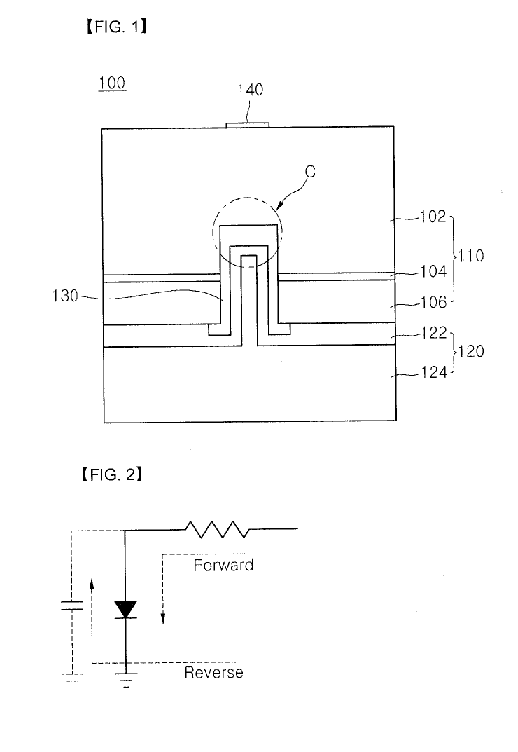

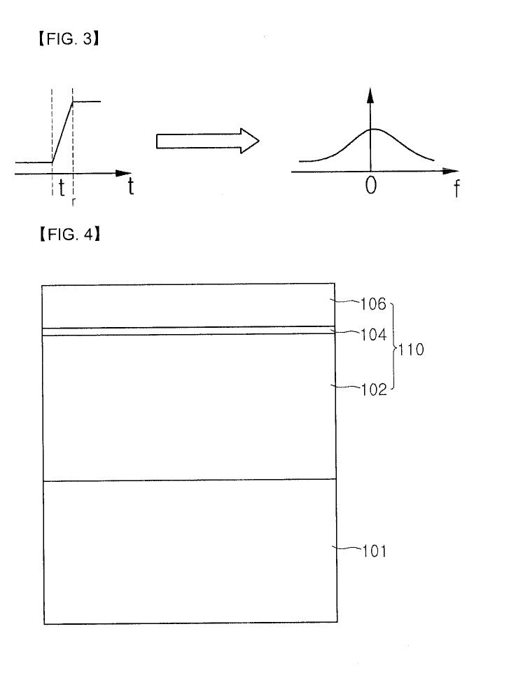

FIG. 1 is a sectional view showing a light emitting device according to a first embodiment, and FIG. 2 is a circuit diagram showing the light emitting device according to the embodiment.

The light emitting device according to the embodiment includes a light emitting structure 110 including a first conductive semiconductor layer 102, an active layer 104, and a second conductive semiconductor layer 106, a dielectric layer 130 formed in a cavity defined by removing a portion of the light emitting structure 110, and a second electrode layer 120 formed on the dielectric layer 130.

According to the embodiment, the first conductive semiconductor layer 102, the dielectric layer 130, and the second electrode layer 120 can carry out the function of a capacitor C. Although one capacitor C is shown in FIG. 1, the embodiment is not limited thereto. According to another embodiment, a plurality of capacitors may be provided.

In the light emitting device and a method of manufacturing the same according to the embodiment, the light emitting device can be prevented from being damaged due to ESD (Electrostatic Discharge) while preventing light absorption from being lowered.

According to the embodiment, when a constant voltage is applied, a current flows to the active layer 104, so that the active layer 104 emits light due to the recombination of carriers. However, in ESD shock, energy having a high-frequency component passes through the path of the dielectric layer 130 of the capacitor C, so that the active layer 104 can be protected.

In other words, according to the embodiment, after forming a dielectric layer in a local region of an LED chip, an electrode is formed over the dielectric layer, thereby forming a capacitor in parallel to the LED. Therefore, when a DC constant voltage is applied, a current flows to a light emitting layer, which is the active layer 104, to emit light. In an ESD shock in the form of a pulse occurring in discharging, energy having a high-frequency component passes through the dielectric layer of the capacitor, so that the light emitting layer can be protected.

According to the embodiment, the capacitor is formed in an LED chip to prevent the LED from being damaged due to ESD, so that package cost can be reduced, and the manufacturing process can be simplified. Accordingly, light absorption can be prevented from being lowered.

According to the embodiment, current flow can be effectively adjusted, so that light extraction efficiency can be improved

According to the embodiment, the reliability for the light emitting device can be improved due to current spreading.

FIG. 2 is a circuit diagram showing the light emitting device according to the embodiment.

According to the embodiment, the first conductive semiconductor layer 102, the dielectric layer 130, and the second electrode layer 120 can perform the function of the MOS (Metal/Oxide/Semiconductor) capacitor C.

The light emitting device according to the embodiment can be realized as the circuit shown in FIG. 2. When a forward voltage is applied according to a constant voltage, a current flows through the LED to emit light. When a reverse voltage is applied according to the ESD, the current flows through the MOS capacitor C.

When the reverse voltage is applied according to ESD, as the total capacitance (C_{Tot}) is increased, a current flowing to the active layer 104 due to the ESD stress is reduced, so that shock can be mitigated.

This will be explained through the following equation.

Q_{Dis}=C_{ESD}V_{ESD} Equation 1
(Q_{Dis}: quantity of charges in discharging, C_{ESD}; capacitance in discharging)
C′_{Tot}=C_{Diode}+C_{MOS} (with MOS)
C_{Tot}=C_{Diode} (without MOS)
I=dQ/dt=ΔQ/τ=Q_{Dis}/(RC_{Tot})∴C_{Tot}↑>I↓↓I′=Q_{Dis}/(RC′)<I=Q_{Dis}/(RC_{Tot})

In other words, when the reverse voltage is applied according to the ESD, as the total capacitance (C_{Tot}) is increased, a current (I′) flowing to the active layer 104 due to the ESD stress is reduced, so that shock can be mitigated.

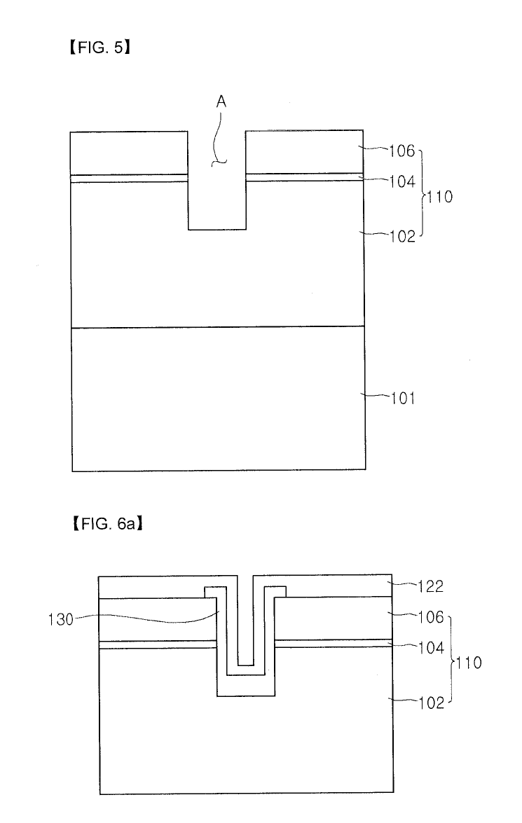

FIG. 3 is a view showing a waveform of the light emitting device according to the embodiment in the ESD.

As shown in FIG. 3, after a pulse waveform has been subject to Fourier Transform, the pulse waveform is transformed into a signal having a high-frequency component. In addition, as the edge of the pulse more sharply rises at rising time (tᵣ), the intensity of the high-frequency component is increased.

As shown in the following Equation, as a frequency is increased, impedance is reduced due to capacitance. Therefore, when a reverse voltage is applied according to the ESD, the impedance of the MOS capacitor C is reduced. Accordingly, a high-frequency current can flow to the MOS capacitor C.

Impedance: Z=Z_{R}+jZ_{Im}

(Z_{R} is Real Impedance, j represents the factor of an imaginary part, and Z_{Im} is impedance made by a capacitor),

Capacitor: Z_{Im,C}=1/(jωC), Equation 2

(wherein, ω=2πf)

In other words, when the reverse voltage is applied according to the ESD, the impedance of the MOS capacitor C is reduced, so that a high-frequency current can flow to the MOS capacitor C.

Meanwhile, according to the embodiment, since a region for a cavity A provided perpendicularly under a first electrode 140 has no active layer 104, light derived from the recombination of carriers (electrons and holes) is not created in the region of the cavity A.

According to the embodiment, after the etching for the light emitting structure is performed from the second conductive semiconductor layer 106 to the active layer 104, the dielectric layer 130 is formed. Accordingly, current is not smoothly supplied to the region for the cavity A. Therefore, light is not emitted from the active layer 104 over the cavity A, so that the light absorption by the first electrode 140 over the cavity A can be minimized.

In the light emitting device and the method of manufacturing the same according to the embodiment, the LED can be prevented from being damaged due to ESD (Electrostatic Discharge) while preventing light absorption from being lowered.

In other words, according to the embodiment, after forming a dielectric layer in a local region of an LED chip, an electrode is formed over the dielectric layer, thereby forming a capacitor in parallel to the LED. Therefore, when a DC constant voltage is applied, a current flows to a light emitting layer, which is the active layer 104, to emit light. In an ESD shock in the form of a pulse occurring in discharging, energy having a high-frequency component passes through the dielectric layer of the capacitor, so that the light emitting layer can be protected.

According to the embodiment, the capacitor is formed in the LED chip to prevent the LED from being damaged due to ESD, so that package cost can be reduced, and the manufacturing process can be simplified. In addition, light absorption can be prevented from being lowered.

According to the embodiment, current flow can be effectively adjusted, so that light extraction efficiency can be improved. In addition, according to the embodiment, the reliability for the light emitting device can be improved due to current spreading.

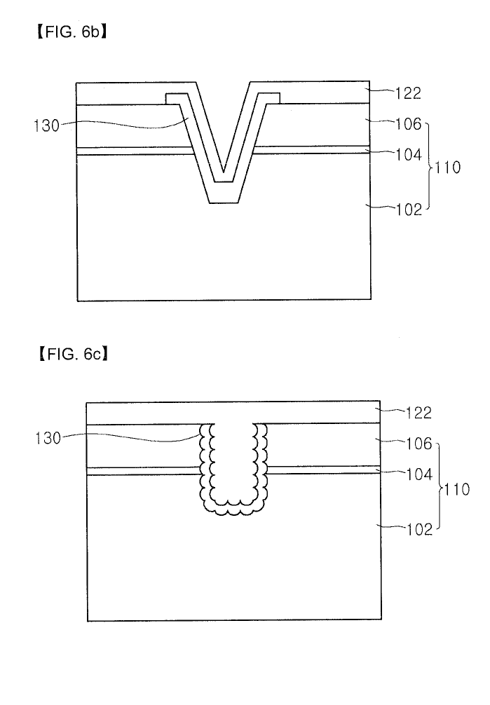

Hereinafter, the method of manufacturing the light emitting device according to the embodiment will be described with reference to FIGS. 4 and 7.

The light emitting device according to the embodiment may include GaN, GaAs, GaAsP, or GaP. For example, a green or blue LED may include GaN (InGaN), and a yellow or red LED may include InGaAIP, or AIGaAs. According to the composition of materials, full colors can be realized.

As shown in FIG. 4, a first substrate 101 is prepared. The first substrate 101 may include a conductive substrate or an insulating substrate. For example, the first substrate 101 may include at least one selected from the group consisting of Al₂O₃, SiC, Si, GaAs, GaN, ZnO, Si, GaP, InP, Ge, and Ga₂0₃. The first substrate 101 may be provided thereon with a concave-convex structure, but the embodiment is not limited thereto.

A wet washing process is performed with respect to the first substrate 101, so that impurities can be removed from the surface of the first substrate 101.

Therefore, the light emitting structure 110 including the first conductive semiconductor layer 102, the active layer 104, and the second conductive semiconductor layer 106 is formed on the first substrate 101.

A buffer layer (not shown) may be formed on the first substrate 101. The buffer layer can attenuate the lattice mismatch between the material of the light emitting structure 110 and the first substrate 101. The buffer layer may include at least one selected from the group consisting of GaN, InN, AlN, InGaN, AlGaN, InAlGaN, and AlInN which are group III-V compound semiconductors. An undoped semiconductor layer may be formed on the buffer layer, but the embodiment is not limited thereto.

The first conductive semiconductor layer 102 may be realized by using group III-V compound semiconductors doped with first conductive dopants. If the first conductive semiconductor layer 102 is an N type semiconductor layer, the first conductive dopant may include Si, Ge, Sn, Se, or Te as the N type dopant, but the embodiment is not limited thereto.

The first conductive semiconductor layer 102 may include a semiconductor material having a composition formula of InₓAl_{y}Ga_{1-x-y}N (0≦x≦1, 0≦y≦1, 0≦x+y≦1).

The first conductive semiconductor layer 102 may include at least one selected from the group consisting of GaN, InN, AlN, InGaN, AlGaN, InAlGaN, AlInN, AlGaAs, InGaAs, AlInGaAs, GaP, AlGaP, InGaP, AlInGaP, and InP.

The first conductive semiconductor layer 102 may include an N type GaN layer formed through a CVD (Chemical Vapor Deposition) scheme, an MBE (Molecular Beam Epitaxy) scheme, a sputtering scheme, or a HVPE (Hydride Vapour Phase Epitaxy) scheme. In addition, the first conductive semiconductor layer 102 may be formed by applying trimethylgallium gas (TMGa), ammonia gas (NH₃), nitrogen gas (N₂), or silane gas (SiH₄) including N type impurities such as Si to the chamber.

Therefore, the active layer 104 is formed on the first conductive semiconductor layer 102. The active layer 104 may include at least one of a single quantum well structure, a multi-quantum well structure, a quantum-wire structure, and a quantum dot structure. For example, the active layer 104 may be formed in the multi-quantum well structure by injecting TMGa, NH₃, N₂, or TMIn, but the embodiment is not limited thereto.

The active layer 104 has a well/barrier layer which is prepared as a pair structure, such as an InGaN/GaN layer, an InGaN/InGaN layer, an AlGaN/GaN layer, an InAlGaN/GaN layer, a GaAs(InGaAs)/AlGaAs layer or a GaP(InGaP)/AlGaP layer, but the embodiment is not limited thereto. The well layer includes material having a band gap lower than that of the barrier layer.

A conductive clad layer may be provided over and/or under the active layer 104. For example, the conductive clad layer may include an AlGaN-based semiconductor, and may have a band gap higher than that of the active layer 104.

Thereafter, the second conductive semiconductor layer 106 is formed on the active layer 104.

The second conductive semiconductor layer 106 may include compound semiconductors of group III-V elements doped with second conductive dopants. For example, the second conductive semiconductor layer 106 may include semiconductor materials having a composition formula of InₓAl_{y}Ga_{1-x-y}N (0≦x≦1, 0≦y≦1, 0≦x+y≦1). The second conductive semiconductor layer 106 may be selected from the group consisting of GaN, AlN, AlGaN, InGaN, InN, InAlGaN, AlInN, AlGaAs. GaP, GaAs, GaAsP, and AlGaInP. If the second conductive semiconductor layer 106 is a P type semiconductor layer, the second conductive dopant may include Mg, Zn, Ca, Sr, or Ba as a P type dopant. The second conductive semiconductor layer 106 may have a single layer structure or a multiple layer structure, but the embodiment is not limited thereto.

The second conductive semiconductor layer 106 may include a P type GaN layer formed by injecting TMGa, NH₃, N₂, and (EtCp₂Mg){Mg(C₂H₅C₅H₄)₂} including P type impurities such as Mg into the chamber, but the embodiment is not limited thereto.

According to the embodiment, the first conductive semiconductor layer 102 may be realized by using an N type semiconductor layer, and the second conductive semiconductor layer 106 may be realized by using a P type semiconductor layer, but the embodiment is not limited thereto. In addition, over the second conductive semiconductor layer 106, a semiconductor, such as an N type semiconductor layer (not shown), having polarity opposite to the polarity of the second conductive semiconductor layer may be formed. Accordingly, the light emitting structure 110 may be realized by using one of an N—P junction structure, a P—N junction structure, an N—P—N junction structure, and a P—N—P junction structure.

As shown in FIG. 5, the cavity A is formed by removing portions of the second conductive semiconductor layer 106, the active layer 104, and the second conductive semiconductor layer 106. The cavity A may include a recess, a groove, a trough or a trench.

For example, an etching process may be performed from a portion of the second conductive semiconductor layer 106, which is provided perpendicularly under the first electrode 140, to be formed later, to a point at which the first conductive semiconductor layer 102 is exposed. In order to form the cavity A, a dry etching process or a wet etching process can be performed.

According to the embodiment, a current is not smoothly supplied to the region for the cavity A, so that light emission does not occur over the cavity A. Accordingly, light absorption by the first electrode 140 provided over the cavity A can be minimized. In addition, according to the embodiment, since the region for the cavity A provided perpendicularly under the first electrode 140 has no active layer 104, light derived from the recombination of carriers (electrons and holes) is not created in the region for the cavity A.

In addition, according to the embodiment, the light emitting structure may be etched from the second conductive semiconductor layer 106 to the active layer 104. Accordingly, the dielectric layer 130 is thereafter formed over the cavity A, so that a constant voltage/current is not smoothly supplied to the region for the cavity A. Accordingly, light emission rarely occurs in the active layer 104 over the cavity A, thereby minimizing light absorption by the first electrode 140 existing over the cavity A.

Thereafter, as shown in FIG. 6A, the dielectric layer 130 is formed over the cavity A. For example, the dielectric layer 130 may be formed over the cavity A by using a nitride layer or an oxide layer including SiO₂, TiO₂, Al₂O₃, Si₃N₄,SrBi₂(Ta, Nb)₂O₉(SBT), Pb(Zr,Ti)O₃(PZT), or Bi₄Ti₃O₁₂(BTO). Even if the dielectric layer 130 has a thin thickness under a condition at which the dielectric layer 130 includes ferroelectricity, the dielectric layer 130 can ensure high capacitance.

According to the embodiment, the dielectric layer 130 may be formed in the second conductive semiconductor layer 106 in addition to lateral and bottom surfaces of the cavity A. Therefore, the dielectric layer 130 may be firmly maintained.

The dielectric layer 130 has a thicker thickness at the lateral surface of the cavity A than at the bottom surface of the cavity A, but the embodiment is not limited thereto.

Thereafter, the second electrode layer 120 is formed between the second conductive semiconductor layer 106 and the dielectric layer 130.

The second electrode layer 120 may include an ohmic layer (not shown), a reflective layer 122, a coupling layer (not shown), and a conductive support substrate 124.

For example, the second electrode layer 120 may include the ohmic layer (not shown). The ohmic layer makes ohmic contact with the light emitting structure 110, so that power is smoothly supplied to the light emitting structure. The ohmic layer may have a stack structure includes single metal, metal alloy, or metal oxide.

For example, the ohmic layer may include at least one of ITO (indium tin oxide), IZO (indium zinc oxide), IZTO (indium zinc tin oxide), IAZO (indium aluminum zinc oxide), IGZO (indium gallium zinc oxide), IGTO (indium gallium tin oxide), AZO (aluminum zinc oxide), ATO (antimony tin oxide), GZO (gallium zinc oxide), IZON (IZO Nitride), AGZO(Al—Ga ZnO), IGZO(In—Ga ZnO), ZnO, IrOx, RuOx, NiO, RuOx/ITO, Ni/IrOx/Au, Ni/IrOx/Au/ITO, Ag, Ni, Cr, Ti, Al, Rh, Pd, Ir, Ru, Mg, Zn, Pt, Au, and Hf.

In addition, the second electrode layer 120 includes the reflective layer 122 to reflect light incident from the light emitting structure 110, so that light extraction efficiency can be improved.

For example, the reflective layer 122 may include metal or alloy including at least one of Ag, Ni, Al, Rh, Pd, Ir, Ru, Mg, Zn, Pt, Au, and Hf. The reflective layer 122 may be formed in a multi-layer structure by using the metal or alloy and a transmissive conductive material such as IZO, IZTO, IAZO, IGZO, IGTO, AZO, or ATO. For example, the reflective layer 122 may have a stack structure of IZO/Ni, AZO/Ag, IZO/Ag/Ni, and AZO/Ag/Ni.

In addition, if the second electrode layer 120 includes a bonding layer (not shown), the reflective layer 122 may act as the bonding layer, or may include barrier metal or bonding metal. For example, the bonding layer may include at least one of Ti, Au, Sn, Ni, Cr, Ga, In, Bi, Cu, Ag, and Ta.

The second electrode layer 120 may include the conductive support substrate 124. The conductive support substrate 124 may supply power to the light emitting structure 110 together with the first electrode 140 while supporting the light emitting structure 110. The conductive support substrate 124 may include metal, metal alloy, or a conductive semiconductor material having superior electrical conductivity.

For example, the conductive support substrate 124 may include at least one of Cu, Cu alloy, Au, Ni, Mo, Cu—W, carrier wafers (e.g., Si, Ge, GaAs, GaN, ZnO, SiGe, or SiC)

The thickness of the conductive support substrate 124 may vary according to the design of the light emitting device 100. For example, the conducive support substrate 124 may have a thickness in the range of about 30 μm to about 500 μm.

The conductive support substrate 124 may be formed through an electro-chemical metal deposition scheme, a plating scheme, or a bonding scheme using eutectic metal.

FIG. 6B is a sectional view showing a cavity according to another embodiment. According to the present embodiment, the cavity may be inclined as shown in FIG. 6B. Accordingly, the dielectric layer 130 or the reflective layer 122 may be formed along an inclined sidewall of the cavity.

FIG. 6C is a sectional view showing a cavity according to still another embodiment. According to the present embodiment, a concave-convex pattern is formed on a sidewall of the cavity as shown in FIG. 6C so that the contact area between the cavity and the dielectric layer 130 can be increased. Accordingly, the capacitance can be increased.

Next, as shown in FIG. 7, the first substrate 101 is removed such that the first conductive semiconductor layer 102 is exposed. The first substrate 101 may be removed through a laser lift off scheme or a chemical lift off scheme. In addition, the first substrate 101 may be physically ground to be removed.

Thereafter, the first electrode 140 may be formed on the first conductive semiconductor layer 102 exposed by removing the first substrate 101.

The first electrode 140 may include a pad part subject to wire bonding, and a finger part extending from the pad part. The finger part may branch in a predetermined pattern, and may have various shapes.

A roughness pattern (not shown) may be formed on a top surface of the first conductive semiconductor layer 102 to improve light extraction efficiency. Accordingly, the roughness pattern may be formed even on the top surface of the first electrode 140, but the embodiment is not limited thereto.

The first electrode 140 may be formed on the first conductive semiconductor layer 102 such that the first electrode 140 spatially overlaps with the cavity A, but the embodiment is not limited thereto. Even if the first electrode 140 slightly overlaps with the cavity A, the effects according to the embodiment can be obtained.

According to the embodiment, since the active layer 104 is not formed at the region of the cavity A provided perpendicularly under the first electrode 140, light derived from the recombination of carriers (electrons and holes) may not be created at the region of the cavity A.

According to the embodiment, since the cavity A, which is an etched region, is covered with the dielectric layer 130, a current does not flow through the cavity A, but is diffused into other regions. In other words, the cavity A is covered with the dielectric layer 130 to act as a CBL (Current Blocking Layer), so that the current can effectively flow. Accordingly, the reliability is not only improved, but also the light absorption by the first electrode 140 can be minimized. Therefore, the quantity of light can be increased. According to the first embodiment, the thickness of the first conductive semiconductor layer 102 may be thicker than that of the dielectric layer 130 or the reflective layer 122, but the embodiment is not limited thereto. According to the second and third embodiments, the first conductive semiconductor layer 102, the dielectric layer 130, and the reflective layer 122 may be formed at various thickness ratios.

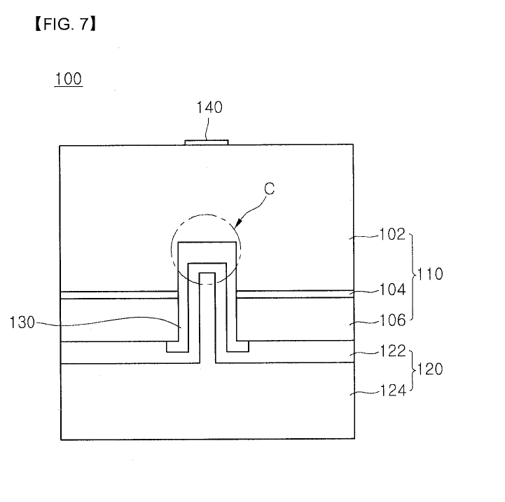

FIG. 8 is a sectional view showing a light emitting device 100b.

As shown in FIG. 8, a second reflective layer 122a may be filled in the cavity A. Accordingly, the conductive layer 124 may be easily formed thereafter.

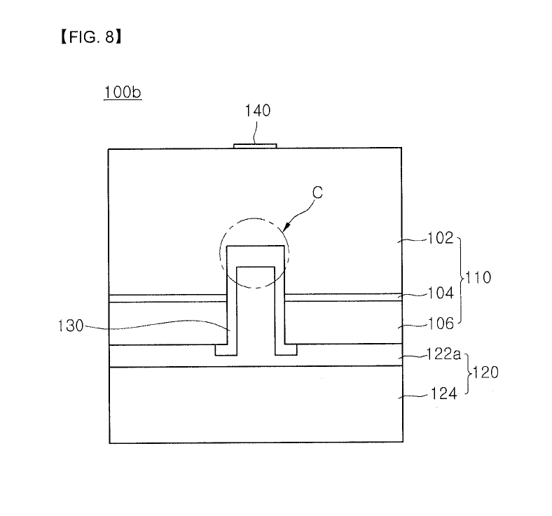

FIG. 9 is a sectional view showing a light emitting device 100c according to a third embodiment.

According to the embodiment, as shown in FIG. 9, a second dielectric layer 130a is filled in a portion of the cavity A, and a third reflective layer 122b may be filled in a remaining portion of the cavity A. In this case, the second dielectric layer 130a is formed to the height of the active layer 104, or a portion of the first conductive semiconductor layer 102.

Meanwhile, the capacitance according to the embodiment can be expressed through the following equation.

C=∈×A/d, Equation 3

wherein ∈ is permittivity of a dielectric layer, A represents the area of the dielectric layer, and d represents the thickness of the dielectric layer.

In Equation 3, as the permittivity and the area of the dielectric layer are increased, and the thickness of the dielectric layer is decreased, capacitance C is increased. Therefore, according to the embodiment, the structure and the characteristics of the dielectric layer may be an important factor to prevent impact from being exerted on an active layer in ESD.

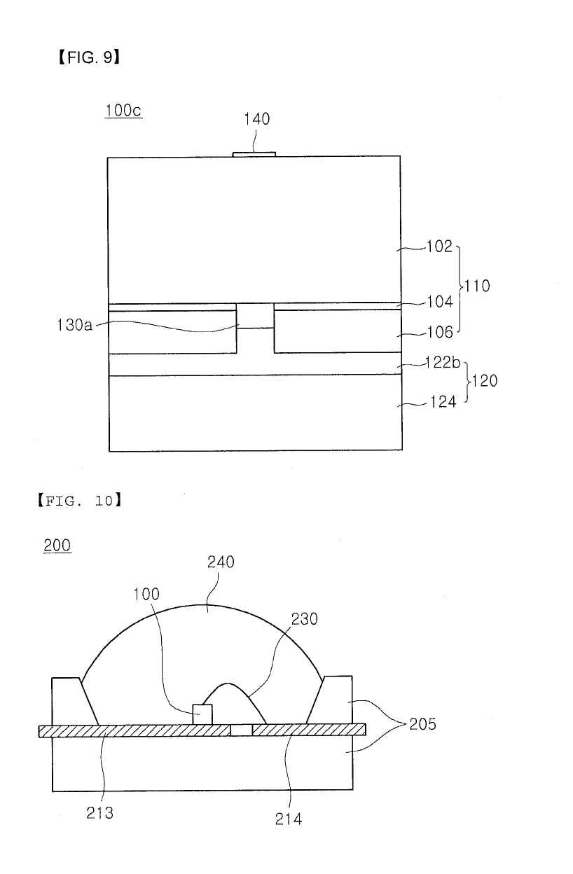

FIG. 10 is a view showing a light emitting device package 200 in which a light emitting device is installed according to the embodiments.

Referring to FIG. 10, the light emitting device package 200 includes a package body 205, third and fourth electrode layers 213 and 214 formed on the package body 205, the light emitting device 100 provided on the package body 205 and electrically connected to the third and fourth electrode layers 213 and 214 and a molding member 240 that surrounds the light emitting device 100.

The package body 205 may include silicon, synthetic resin or metallic material. An inclined surface may be formed around the light emitting device 100.

The third and fourth electrode layers 213 and 214 are electrically isolated from each other to supply power to the light emitting device 100. In addition, the third and fourth electrode layers 213 and 214 reflect the light emitted from the light emitting device 100 to improve the light efficiency and dissipate heat generated from the light emitting device 100 to the outside.

The vertical type light emitting device shown in FIGS. 1, 8, and 8, is applicable to the light emitting device 100, but the embodiment is not limited thereto. For instance, the lateral type light emitting device may be applicable to the light emitting device 100.

The light emitting device 100 may be installed on the package body 205 or the third and fourth electrode layers 213 and 214.

The light emitting device 100 is electrically connected to the third electrode layer 213 and/or the fourth electrode layer 214 through at least one of a wire bonding scheme, a flip chip bonding scheme and a die bonding scheme. According to the embodiment, the light emitting device 100 is electrically connected to the third electrode layer 213 through a wire 230 and electrically connected to the fourth electrode layer 214 through the die bonding scheme.

The molding member 240 surrounds the light emitting device 100 to protect the light emitting device 100. In addition, the molding member 240 may include phosphors to change the wavelength of the light emitted from the light emitting device 100.

A plurality of light emitting device packages according to the embodiment may be arrayed on a substrate, and an optical member including a light guide plate, a prism sheet, a diffusion sheet or a fluorescent sheet may be provided on the optical path of the light emitted from the light emitting device package. The light emitting device package, the substrate, and the optical member may serve as a backlight unit or a lighting unit. For instance, the lighting system may include a backlight unit, a lighting unit, an indicator, a lamp or a streetlamp.

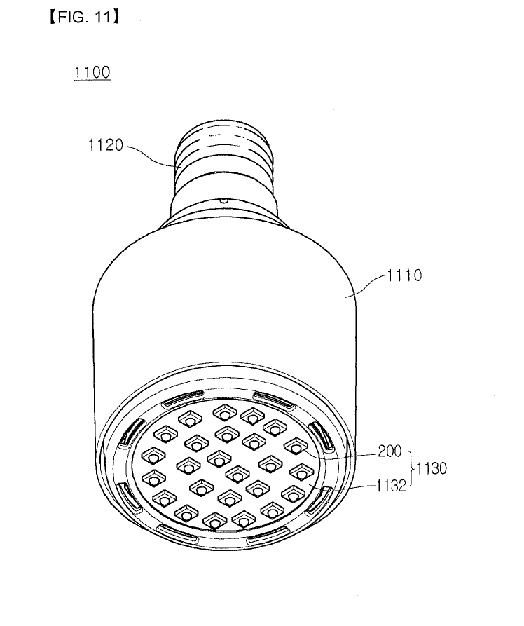

FIG. 11 is a perspective view showing a lighting unit 1100 according to the embodiment. The lighting unit 1100 shown in FIG. 11 is an example of a lighting system and the embodiment is not limited thereto.

Referring to FIG. 11, the lighting unit 1100 includes a case body 1110, a light emitting module 1130 installed in the case body 1110, and a connection terminal 1120 installed in the case body 1110 to receive power from an external power source.

Preferably, the case body 1110 includes material having superior heat dissipation property. For instance, the case body 1110 includes metallic material or resin material.

The light emitting module 1130 may include a substrate 1132 and at least one light emitting device package 200 installed on the substrate 1132.

The substrate 1132 includes an insulating member printed with a circuit pattern. For instance, the substrate 1132 includes a PCB (printed circuit board), an MC (metal core) PCB, an F (flexible) PCB, or a ceramic PCB.

In addition, the substrate 1132 may include material that effectively reflects the light. The surface of the substrate 1132 can be coated with a color, such as a white color or a silver color, to effectively reflect the light.

At least one light emitting device package 200 can be installed on the substrate 1132. Each light emitting device package 200 may include at least one LED (light emitting diode). The LED may include a colored LED that emits the light having the color of red, green, blue or white and a UV (ultraviolet) LED that emits UV light.

The LEDs of the light emitting module 1130 can be variously arranged to provide various colors and brightness. For instance, the white LED, the red LED and the green LED can be arranged to achieve the high color rendering index (CRI).

The connection terminal 1120 is electrically connected to the light emitting module 1130 to supply power to the light emitting module 1130. Referring to FIG. 11, the connection terminal 1120 has a shape of a socket screw-coupled with the external power source, but the embodiment is not limited thereto. For instance, the connection terminal 1120 can be prepared in the form of a pin inserted into the external power source or connected to the external power source through a wire.

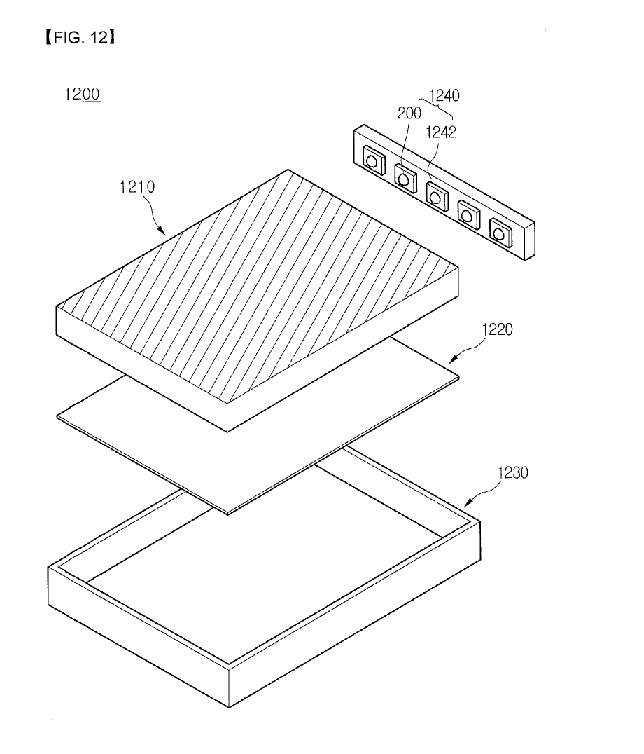

FIG. 12 is an exploded perspective view showing a backlight unit 1200 according to the embodiment. The backlight unit 1200 shown in FIG. 12 is an example of a lighting system and the embodiment is not limited thereto.

The backlight unit 1200 according to the embodiment includes a light guide plate 1210, a light emitting module 1240 for providing the light to the light guide plate 1210, a reflective member 1220 positioned under the light guide plate 1210, and a bottom cover 1230 for receiving the light guide plate 1210, light emitting module 1240, and the reflective member 1220 therein, but the embodiment is not limited thereto.

The light guide plate 1210 diffuses the light to provide surface light. The light guide 1210 includes transparent material. For instance, the light guide plate 1210 can be manufactured by using acryl-based resin, such as PMMA (polymethyl methacrylate), PET (polyethylene terephthalate), PC (polycarbonate), COC or PEN (polyethylene naphthalate) resin.

The light emitting module 1240 supplies the light to at least one lateral side of the light guide plate 1210 and serves as the light source of the display device including the backlight unit.

The light emitting module 1240 can be positioned adjacent to the light guide plate 1210, but the embodiment is not limited thereto. In detail, the light emitting module 1240 includes a substrate 1242 and a plurality of light emitting device packages 200 installed on the substrate 1242 and the substrate 1242 can be adjacent to the light guide plate 1210, but the embodiment of not limited thereto.

The substrate 1242 may include a printed circuit board (PCB) having a circuit pattern (not shown). In addition, the substrate 1242 may also include a metal core PCB (MCPCB) or a flexible PCB (FPCB), but the embodiment is not limited thereto.

In addition, the light emitting device packages 200 are arranged such that light exit surfaces of the light emitting device packages 200 are spaced apart from the light guide plate 1210 at a predetermined distance.

The reflective member 1220 is disposed under the light guide plate 1210. The reflective member 1220 reflects the light, which is traveled downward through the bottom surface of the light guide plate 1210, toward the light guide plate 1210, thereby improving the brightness of the backlight unit. For instance, the reflective member 1220 may include PET, PC or PVC resin, but the embodiment is not limited thereto.

The bottom cover 1230 may receive the light guide plate 1210, the light emitting module 1240, and the reflective member 1220 therein. To this end, the bottom cover 1230 has a box shape with an open top surface, but the embodiment is not limited thereto.

The bottom cover 1230 can be manufactured through a press process or an extrusion process by using metallic material or resin material.

In the light emitting device, the light emitting device package, and the lighting system according to the embodiment, the LED can be prevented from being damaged due to ESD while preventing light absorption from being lowered.

In other words, according to the embodiment, after forming a dielectric layer in a local region of an LED chip, an electrode is formed over the dielectric layer, thereby forming a capacitor in parallel to the LED. Therefore, when a DC constant voltage is applied, a current flows to a light emitting layer, which is the active layer, to emit light. In contrast, in an ESD shock in the form of a pulse occurring in discharging, energy having a high-frequency component passes through the dielectric layer of the capacitor, so that the light emitting layer can be protected.

According to the embodiment, the capacitor is formed in an LED chip to prevent the LED from being damaged due to static electricity, so that package cost can be reduced, and the manufacturing process can be simplified. In addition, the light absorption can be prevented from being lowered.

According to the embodiment, current flow can be effectively adjusted, so that light extraction efficiency can be improved.

According to the embodiment, the reliability for the light emitting device can be improved due to current spreading.

As described above, the lighting system according to the embodiments includes the light emitting device package according to the embodiments, so that the reliability of the lighting system can be improved.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

1. A light emitting device comprising:
a light emitting structure including a second conductive semiconductor layer, an active layer over the second conductive semiconductor layer, and a first conductive semiconductor layer over the active layer;
a dielectric layer in a cavity defined by removing a portion of the light emitting structure; and
a second electrode layer over the dielectric layer,
wherein the second electrode includes:
a reflective layer over the dielectric layer; and
a conductive layer over the reflective layer.

2. The light emitting device of claim 1, wherein the cavity is formed by removing the light emitting structure from the second conductive semiconductor layer to the active layer until a portion of the first conductive semiconductor layer is exposed.

3. The light emitting device of claim 1, wherein the reflective layer is formed at a portion of the cavity.

4. The light emitting device of claim 1, wherein the reflective layer is filled in the cavity.

5. The light emitting device of claim 1, further comprising a first electrode over the first conductive semiconductor layer, wherein the first electrode spatially overlaps with a portion of the cavity.

6. The light emitting device of claim 1, wherein a current flows to the active layer to emit light when a constant voltage is applied, and a high-frequency passes through the dielectric layer in electrostatic discharge.

7. The light emitting device of claim 1, wherein a predetermined roughness is formed over a surface of the cavity.

8. The light emitting device of claim 1, wherein the dielectric layer has a thicker thickness at a lateral surface of the cavity than at a bottom surface of the cavity.

9. The light emitting device of claim 1, wherein the dielectric layer is filled in a portion of the cavity, and the reflective layer is filled in a remaining portion of the cavity.

10. A light emitting device comprising:
a light emitting structure including a second conductive semiconductor layer, an active layer over the second conductive semiconductor, and a first conductive semiconductor layer over the active layer;
a capacitor in a cavity defined by removing a portion of the light emitting structure; and
a first electrode over the light emitting structure,
wherein the capacitor includes:
a dielectric layer over the cavity; and
a second electrode layer over the dielectric layer.

11. The light emitting device of claim 10, wherein the second electrode layer includes:
a reflective layer over the dielectric layer; and
a conductive layer over the reflective layer.

12. The light emitting device of claim 11, wherein the reflective layer is formed at a portion of the cavity.

13. The light emitting device of claim 11, wherein the reflective layer is filled in the cavity.

14. The light emitting device of claim 10, wherein the first electrode spatially overlaps with a portion of the cavity.

15. The light emitting device of claim 10, wherein a current flows to the active layer to emit light when a constant voltage is applied, and a high-frequency passes through the capacitor in electrostatic discharge

16. The light emitting device of claim 10, wherein a predetermined concave-convex pattern is formed over a surface of the cavity.

17. The light emitting device of claim 11, wherein the dielectric layer is filled in a portion of the cavity, and the reflective layer is filled in a remaining portion of the cavity.

18. The light emitting device of claim 10, wherein the dielectric layer has a thicker thickness at a lateral surface of the cavity than at a bottom surface of the cavity.

19. A light emitting device package including
the light emitting device according to claim 1 and further comprising a package body and third and fourth electrode layers provided on the package body, the light emitting device electrically connected to the third and fourth electrode layers.

20. A light emitting device package including the light emitting device according to claim 10 and further comprising a package body and third and fourth electrode layers provided on the package body, the light emitting device electrically connected to the third and fourth electrode layers.
